(19) United States
(12) Patent Application Publication
(10) Pub. No.: US 2011/0111333 A1
(43) Pub. Date: May 12, 2011

(54) HEAT-RESISTANT FLEXIBLE COLOR FILTER

(75) Inventors: I-Jein Cheng, Changhua City (TW); Chin-Cheng Weng, Kaohsiung City (TW); Kuo-Tung Huang, Hsinchu County (TW); Chyi-Ming Leu, Hsinchu County (TW); Te-Yi Chang, Bade City (TW); Ming-Tzung Wu, Yunlin County (TW)

(73) Assignee: INDUSTRIAL TECHNOLOGY RESEARCH INSTITUTE, Hsinchu County (TW)

(21) Appl. No.: 12/854,308

(22) Filed: Aug. 11, 2010

(30) Foreign Application Priority Data
Nov. 12, 2009 (TW) 098138371

(51) Int. Cl. G03F 1/00

(52) U.S. Cl. 430/7; 977/773

(57) ABSTRACT

The invention provides a heat-resistant flexible color filter, including: a flexible transparent substrate, wherein the forming material thereof includes nano silica and polyimide, and the nano silica is present in an amount of about 20-70 wt %, based on 100 wt % of the forming material; and a heat-stable color photoresist material coated on the flexible transparent substrate, wherein the heat stable color photoresist material includes: a base soluble resin system about 30-90 wt %; a photosensitive system about 5-60 wt %; and a pigment coated with an inorganic alkoxide about 10-50 wt %.

### CROSS REFERENCE TO RELATED APPLICATIONS

This Application claims priority of Taiwan Patent Application No. 098138371, filed on Nov. 12, 2009, the entirety of which is incorporated by reference herein.

### BACKGROUND OF THE INVENTION

1. Field of the Invention

The present invention relates to a color filter, and in particular relates to a heat-resistant flexible color filter formed of a nano silica/polyimide hybrid substrate and a heat stable color photoresist material.

2. Description of the Related Art

The fabrication of a color filter of a TFT liquid crystal display comprises forming a photosensitive black resin for black matrix, and red, green and blue color photoresist for filtering light, wherein the color photoresist must have high light transparency and color saturation. The pigments used in the color filter in the past were able to achieve the requirements of high transparency and color saturation; however, the light resistance and heat resistance of the pigments are not good. In order to overcome the problem, the pigment dispersing method has replaced the pigment method to be the standard method. With the development of large scale television plates, high brightness which raises the temperature of the plates is required. Moreover, in order to achieve high color saturation, pigment particles had to be decreased to prevent scattering. As a result of these changes, the previous pigment used for the color filter is no longer able to achieve the liquid crystal display requirements

The development of active flexible liquid crystal displays mainly comprises flexible color filters and flexible TFTs. There are still many problems with the material and the process of forming color filters and flexible TFTs that need to be solved. Developing a flexible substrate with high transparency, high heat resistance and a low coefficient of thermal expansion is the main challenge. In addition, pigmented photoresists with high heat resistance and low coefficient of thermal expansion are needed in the fabrication process of flexible color filter, and the regulation of interface properties of the substrate and the photoresists is an important challenge in developing a flexible color filter.

### BRIEF SUMMARY OF THE INVENTION

The invention provides a heat-resistant flexible color filter, comprising: a flexible transparent substrate, wherein the forming material thereof comprises nano silica and polyimide, and the nano silica is present in an amount of about 20-70 wt %, based on 100 wt % of the forming material; and a heat-stable color photoresist material coated on the flexible transparent substrate, wherein the heat stable color photoresist material comprises: a base soluble resin system about 30-90 wt %; a photosensitive system about 5-60 wt %; and a pigment coated with an inorganic alkoxide about 10-50 wt %.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A and FIG. 1B show the optical microscope photographs of Example 2 and Comparative example 2 after development, respectively.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The formation of a heat-resistant flexible color filter of the invention is described in the following.

First, a flexible transparent substrate and a heat stable color photoresist material are provided. The forming material of the flexible transparent substrate comprise nano silica and polyimide, wherein the nano silica has properties of high transparency, high thermal-resistance and low coefficient of thermal expansion, and the polyimide has properties of high transparency, high thermal-resistance and well flexibility.

In the formation process of the nano silica/polyimide hybrid substrate, first, nano silica is dispersed in an organic solvent with a solid content less than 40%. The size of the silica is between 10 nm and 400 nm. The organic solvent may comprise DMAC, DMF, DMSO or r-butyrolactone.

Next, a polyimide solution is added into the nano silica solution, wherein the nano silica is present in an amount of about 20-70 wt %, based on 100 wt % of the forming material of the flexible transparent substrate, preferably 30-60 wt %.

The polyimide mentioned above may be synthesize by a typical polycondensation reaction, wherein there are two types of polycondensation methods. In the first method, the polyimide is prepared by, first, reacting a diamine monomer with a dianhydride monomer in a polar solvent to prepare a precursor-poly amic acid (PAA). Next, the precursor is subjected to a thermal (300-400° C.) or chemical treatment to undergo an imidization to let the precursor be dehydrated and closed loop to form polyimide. In another method, a diamine monomer is reacted with a dianhydride monomer in a phenolic solution such as m-cresol, or Cl-phenol and heated to reflux to form polyimide.

The polyimide mentioned above is represented by formula (I):

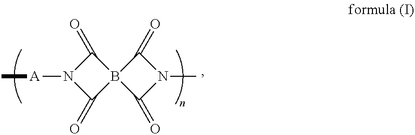

wherein, n is an integer about of 15-10000.

A of formula (I) is cycloalkyl group, heterocyclic group, cycloalkyl group or heterocyclic group with one or more unsaturated bond, aryl group, heteroaryl group, aliphatic group, cycloaliphatic diene group, arylalkyl group or heteroarylalkyl group, and each ring has 3 to 8 carbon atoms. In some embodiments, a hydrogen atom bonded to a cyclic atom of A is substituted optionally by halogen, alkyl group, thioalkyl group, alkoxy group, alkenyl group, alkynyl group, alkenoxy group alkynoxy group or aryl group, wherein the alkyl group, thioalkyl group, alkoxy group, alkenyl group, alkynyl group, alkenoxy group or alkynoxy group has 1 to 12 carbon atoms and is straight or branched.

In one embodiment, A is

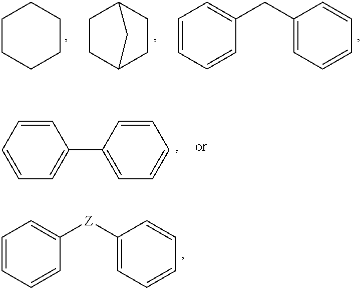

and wherein Z is O, —CH₂—, —C(CH₃)₂—, —Ar—O—Ar—, Ar—CH₂—Ar—, —Ar—C(CH₃)₂—Ar— or —Ar—SO₂—Ar—, and Ar represents benzene, and a hydrogen atom bonded to a cyclic atom of A is substituted optionally by halogen, alkyl group, thioalkyl group, alkoxy group, alkenyl group, alkynyl group, alkenoxy group alkynoxy group or aryl group.

In another embodiment, A is

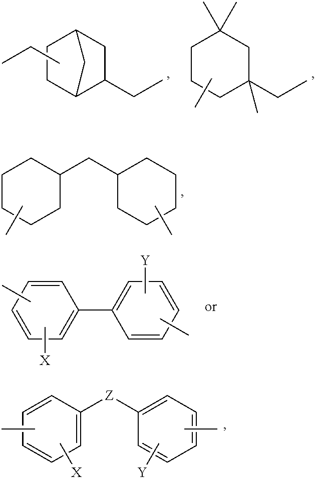

and wherein X and Y are —H, —CH₃, —R, —CF3, —OH, —OR, —Br, —Cl or —I, and R represents an alkyl group having 1-18 carbon atoms, and Z is —O—, —S—, —CH₂—, —C(CH₃)₂—, —SO₂—, —Ar—O—Ar—, —Ar—CH₂—Ar—, —O—Ar—Ar—O—, —O—Ar—C(CF₃)₂—Ar—O—, —O—Ar—C(CH₃)₂—Ar—O—, —O—Ar—SO₂—Ar—O—, and Ar represents benzene.

In addition, B is one or more kinds of cycloalkyl group, heterocyclic group, cycloalkyl group or heterocyclic group with one or more unsaturated bond, aryl group, heteroaryl group, aliphatic group, cycloaliphatic diene group, arylalkyl group or heteroarylalkyl group, and each ring has 3 to 8 carbon atoms. In some embodiments, a hydrogen atom bonded to a cyclic atom of B is substituted by halogen, alkyl group, thioalkyl group, alkoxy group, alkenyl group, alkynyl group, alkenoxy group alkynoxy group or aryl group, wherein the alkyl group, thioalkyl group, alkoxy group, alkenyl group, alkynyl group, alkenoxy group or alkynoxy group has 1 to 12 carbon atoms and is straight or branched.

In one embodiment, B is

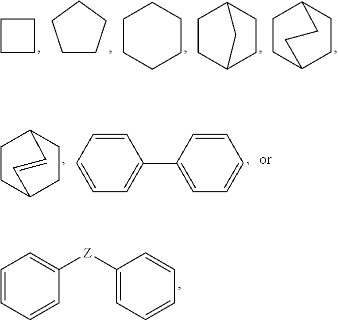

and wherein Z is O, —CH₂—, —C(CH₃)₂—, —Ar—O—Ar—.Ar—CH₂—Ar—, —Ar—C(CH₃)₂—Ar— or —Ar—SO₂—Ar—, and Ar represents benzene, and a hydrogen atom bonded to a cyclic atom of B is substituted by halogen, alkyl group, thioalkyl group, alkoxy group, alkenyl group, alkynyl group, alkenoxy group alkynoxy group or aryl group.

In another embodiment, B is

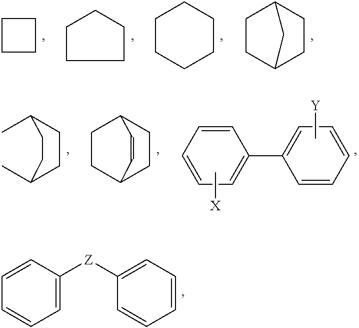

and X and Y are —H, —CH₃, —R, —CF₃, —OH, —OR, —Br, —Cl or —I, and R represents an alkyl group having 1-18 carbon atoms, and Z is —O—.—S—, —CH₂—, —C(CH₃)₂—, —SO₂—, —Ar—O—Ar—, —Ar—CH₂—Ar—, —O—Ar-Ar—O—, —O—Ar—C(CF₃)₂—Ar—O—, —O—Ar—C(CH₃)₂—Ar—O—, —O—Ar—SO₂—Ar—O—, and Ar represents benzene.

After nano silica and polyimide are well mixed, a siloxane surfactant may be further added the mixture to participate in the reaction to form a nano silica/polyimide hybrid material. Then, the nano silica/polyimide complex material is solidified to form a flexible transparent substrate. The siloxane surfactant may comprise a siloxane surfactant with polar functional groups. The siloxane surfactant with polar functional groups may comprise aminosiloxane or isocynate silane.

The heat stable color photoresist material comprises a base soluble resin system about 30-90 wt %, a photosensitive system about 5-60 wt %, and a pigment coated with a inorganic alkoxide about 10-50 wt %.

The base soluble resin system may comprise a homopolymer or copolymer of vinylated unsaturated monomers. The vinylated unsaturated monomer may comprise methacrylate, such as methyl (meth)acrylate, benzyl (meth)acrylate, ethyl (meth)acrylate, 2-hydroxyethyl (meth)acrylate, hydroxylpropyl (meth)acrylate), isobutyl (methy)acrylate), etc., or acrylate, such as methyl acrylate, benzyl acrylate, ethyl acrylate, 2-hydroxyethyl acrylate, hydroxylpropyl acrylate, isobutyl acrylate, 3-(trimethoxysilyl)propyl methacrylate or 3-(trimethoxysilyl)propyl methacrylate, etc.

In one embodiment, the base soluble resin comprises a copolymer of vinylated unsaturated monomers with silane structures and vinylated unsaturated monomers without silane structure, wherein the vinylated unsaturated monomers with silane structures are present in an amount less than about 20 mol %, based on 100 mol % of the copolymer.

In another embodiment, the base soluble resin comprises an acrylic polymer with an acid group, wherein the acid group may be methacrylic acid or acrylic acid etc.

Further, in another embodiment, the base soluble resin is a copolymer of vinylated unsaturated monomer with acid groups, such as methacrylic acid or acrylic acid, and other vinylated unsaturated monomers or vinylated unsaturated monomers with silane structures, wherein the monomers with acid groups in the copolymer are about 10-50%, preferably about 20-40%. A weight average molecular weight (g/mol) of the copolymer is about 1000-100,000, preferably about 6,00-20,000.

The photosensitive system may comprise a multifunctional monomer with more than two double bonds, and a photoinitiator.

More than two of the multifunctional monomers may be cross-linked to form a network structure. The multifunctional monomer may comprise ethylene glycol dimethacrylate, 1,4-butanediol diacrylate, diethylene glycol diacrylate (DEGDA), pentaerythritol triacrylate, ethoxylated trimethylolpropane triacrylate, dipentaerythritol pentaacrylate, ethoxylated pentaerythritol tetraacrylate, pentaerythritol tetraacrylate or dipentaerythritol hexaacrylate, etc.

An organic compound which is able to release free radical under UV light with broad band wavelength illuminating to perform a crosslinking reaction may be selected as the photoinitiator. A preferable photoinitiator is a photoinitiator with high efficacy under a UV light with a wavelength of 400 nm illuminating, such as:

(1) Acetophenone: 2-Methyl-1-(4-(methylthio)phenyl)-2-morpholino-propane-1,1-Hydroxy cyclohexyl phenyl ketone, Diethoxyacetophenone, 2-Hydroxy-2-methyl-1-phenyl-propane-1-one, 2-Benzyl-2-(dimethylamino)-1-[4-(4-morpholinyl)phenyl]-1-butanone, etc.; (2) Benzoin: Benzoin, Benzoin methyl ether, Benzyl dimethyl ketal; (3) Benzophenone: Benzophenone, 4-Phenyl benzophenone, Hydroxyl benzophenone, etc.; (4) Thioxanthone: Isopropylthioxanthone, 2-Chlorothioxanthone, etc.; and (5) anthraquinone: 2-ethylanthraquinone.

Moreover, the photoinitiator may be used alone or in a mixed use configuration, for example; mixing isopropylthioxanthone and 2-Benzyl-2-(dimethylamino)-1-[4-(4-morpholinyl)phenyl]-1-butanone may obtain a high shutter speed.

A method for forming the pigment coated with an inorganic alkoxide is to use a sol-gel process to let a reactive inorganic alkoxide perform condensation polymerization and coat over the outer layer of the pigment particles.

The inorganic alkoxide is represented by formula (II):

R-M-(OR′)ₙX₃₋ₙ formula (II),

wherein, M is a metal, such as titanium, or is silicon, R is H, C₁₋₁₈ alkyl group, aryl group, alkyl vinyl group, alkyl amine group, alkyl nitrile, alkyl isocyanate, alkyl epoxide group or OR′, R′ is C₁₋₆ alkyl group, X is halogen, —OH, —NCO or C₁₋₆ alkyl group, and n is an integer about of 1-3.

Before the inorganic alkoxide is coated over the pigment particles, the pigment particles are dispersed, first. The dispersal method calls for the pigment to be immersed in an organic solvent, such as THF for 30 minutes and then grinded down and dispersed to reduce the particle size of the pigment particles. In addition, in the method mentioned above, a catalyst may be added to perform the condensation polymerization reaction. The condensation polymerization reaction is achieved through solvent volatilization at high maturation temperatures. The temperature of the condensation polymerization reaction is 30-150° C., preferably 70-120° C. Thermal-resistance and hyrophility of the pigment coated with the inorganic alkoxide is substantially increased. This raises the stability of the pigment during the process and increases the applications of the pigment thereof.

The catalyst mentioned above may be an acid catalyst of inorganic acid or organic acid, or an alkaline catalyst of an inorganic base or organic base. The acid catalyst, for example may be HNO_{3(aq)}, H₂SO_{4(aq)}, HCl_{(aq)}, HBr_{(aq)}, HI_{(aq)}, HClO_{4(aq)}, acetic acid or glacial acetic acid, etc. The alkaline catalyst, for example may be NaOH_{(aq)}, NH_{3(aq)}, NaNH₂, CH₃OK, KOH, primary amine, secondary amine or tertiary amine. The preferable acid catalyst is HCl_{(aq)}, HI_{(aq)} or acetic acid, and the preferable alkaline catalyst is NaOH_{(aq)} or NH_{3(aq)}.

The heat stable color photoresist material is obtained by mixing the base soluble resin system, the photosensitive system and the pigment coated with the inorganic alkoxide mentioned above.

The solid content of the heat stable color photoresist material may be 10-40%, according to the coating method used and thickness of the coating to be formed, the solid content of the heat stable color photoresist material may be adjusted. If the thickness of the coating needs to be control at 1-1.5 μm, the solid content of the heat stable color photoresist material should be adjusted to 18-28% . The preferable content of each ingredient of the heat stable color photoresist material is shown in Table 1.

TABLE 1
The ingredients of the heat stable color photoresist material:

| Ingredient | Content (wt %) |
|---|---|
| Bse soluble resin | 6-20 |
| Multifunctional monomer | 4-7 |
| Photoinitiator | 1-5 |
| Pigment coated with the inorganic | 2-10 |
| alkoxide | |
| Dispersant | 0.8-10 |
| Solvent | 85-60 |

In one embodiment, a method for forming the heat stable color photoresist material may be to first disperse the pigment coated with the inorganic alkoxide with the dispersant, then add the multifunctional monomer and photoinitiator and then mix well, and finally adding the other ingredients. After mixing at high speed, the heat stable color photoresist material is ready for use.

Finally, the heat stable color photoresist material mentioned above is coated on the flexible transparent substrate and the coating method may comprise spin coating, slit die coating or ink jet coating. Next, the substrate is pre-braked and then the heat stable color photoresist material coated on the substrate is exposed by using a mask with a specific pattern, developed with an alkaline solution, wherein the unexposed part is washed out by the alkaline solution and the exposed pattern part is retained. The resulting pattern is washed with water, dried and then baked to complete the process for processing the photoresist material. Then, the process is repeated to be applied to red, green, blue photoresistant, etc. and corresponding masks, respectively to complete the fabrication of the heat-resistant flexible color filter of the invention. The heat-resistant flexible color filter of the invention may be fabricated from the exiting development techniques, and is effective in the areas of; high dimensional stability, low chromatism and low coefficient of thermal expansion, wherein the coefficient of thermal expansion thereof is about 8-30. The heat stable color photoresist material of the invention, in addition to being applicable to the nano silica/polyimide hybrid substrate, can also be applied to other polymer substrate, such as polyethylene terephthalate (PET), polyether sulfone (PES), etc. not be limited to polyimide mentioned above.

### EXAMPLE

### 1. Synthesis of the Polyimide

(1) Synthesis of the polyimide B1317 (bicyclo[2.2.2]oct-7-ene-2,3,5,6-tetracarboxylic dianhydride -BAPPm(4,4-bis(4-aminophenoxy)propane), (BB)

At room temperature, under nitrogen atmosphere, 0.0147 mole of BAPPm was dissolved in 32.94 g of m-cresol. After BAPPm dissolved completely, 0.015 mole of B1317 was added and a stringy mixture was formed after the B1317 dissolved completely and was stirred for one hour. Next, the stringy mixture was heated to 220° C. for 3 hours and ground water was removed during heating to form a reactive solution. Then, the reactive solution was dropped into methonal to precipitate polyimide and the precipitate was dried in a vacuum oven for 12 hours. After determining by a gel permeation chromatography, the result showed that Mn, Mw and Mw/Mn of the resultant product were 39381, 11011539 and 25.69, respectively.

### 2. Preparation of the Flexible Transparent Substrate

(1) Substrate 1: Synthesis of Nano Silica/Polyimid B1317-BAPPm (SiO₂/BB=3/7) Hybrid Substrate

At room temperature, 3 g of nano silica was dispersed in DMAc with 20% solid content and 7 g of B1317-BAPPm dissolved in DMAc with 20% solid content were placed into a 20 g sample bottle and 0.3 g of siloxane with amino group was added into the bottle to form a mixture. The mixture was stirred at room temperature for 30 minutes, scraped on a glass plate, then placed into a oven and baked at 80° C. and 150° C. for 1 hour, respectively, and taken out to obtain the nano silica/polyimid B1317-BAPPm (SiO₂/BB=3/7) hybrid substrate.

(2) Substrate 2: Synthesis of Nano Silica/Polyimid B1317-BAPPm (SiO₂/BB=5/5) Hybrid Substrate

At room temperature, 5 g of nano silica dissolved in DMAc with 20% solid content and 5 g of B1317-BAPPm dissolved in DMAc with 20% solid content were placed into a 20 g sample bottle and 0.2 g of siloxane with amino group was added into the bottle to form a mixture. The mixture was stirred at room temperature for 30 minutes, scraped on a glass plate, then placed into a oven and baked at 80° C. and 150° C. for 1 hour, respectively, and taken out to obtain the nano silica/polyimid B1317-BAPPm (SiO₂/BB=5/5) hybrid substrate.

(3) Substrate 3: Synthesis of Nano Silica/Polyimid B1317-BAPPm (SiO₂/BB=7/3) Hybrid Substrate

At room temperature, 7 g of nano silica dissolved in DMAc with 20% solid content and 3 g of B1317-BAPPm dissolved in DMAc with 20% solid content were placed into a 20 g sample bottle and 0.12 g of siloxane with amino group was added into the bottle to form a mixture. The mixture was stirred at room temperature for 30 minutes, scraped on a glass plate, then placed into a oven and baked at 80° C. and 150° C. for 1 hour, respectively, and taken out to obtain the nano silica/polyimid B1317-BAPPm (SiO₂/BB=7/3) hybrid substrate.

The properties of the substrate 1, 2 and 3 are shown in Table 2.

TABLE 2
Properties of the substrate 1, 2 and 3

| | | Thickness | CTE | TT | |
|---|---|---|---|---|---|
| | | (μm) | (ppm/° C.) | (%) | b |
| | BB | 57 | 75.4 | 89.3 | 1.95 |
| Substrate 1 | SiO₂/BB = 3/7 | 53 | 56.6 | 89.5 | 2.01 |
| Substrate 2 | SiO₂/BB = 5/5 | 52 | 48.6 | 89.6 | 2.13 |
| Substrate 3 | SiO₂/BB = 7/3 | 51 | 28.3 | 90.1 | 2.25 |

(International Commission on Illumination, CIE L*a*b*, L=light brightness; a=red-green axis; b=blue-yellow axis)

### 3. Preparation of the Pigment Coated with a Inorganic Alkoxide

(1) Pigment 1 (Coated with a Inorganic Alkoxide)

100 g THF solvent, and then 40 g red pigment (Pigment Red 254,Ciba) and 5 g 3-Aminopropyltriethoxysilane (surface-modification additive) were added in to a 250 ml polyethylene (PE) grinding tank containing ½ the grinding tank volume of zirconium balls with a diameter of 1 mm to form a mixed solution and the mixed solution was dispersed by the grinding machine for two hours and taken out and put in a 250 g circular bottom bottle and 1.7 g HCl aqueous solution was added into the circular bottom bottle and stirred. Then, 5 g triethoxymethyl silane (TEOS) was added into the circular bottom bottle. This 5 g triethoxymethyl silane (TEOS) in the 1.7 g aqueous solution performed a hydrolysis reaction. The entire solution was stirred for 24 hours and after THF evaporating, high temperature maturation for 8 hours to complete the condensation reaction, the resultant product was wash 4 times by pure water and dried for ready for use.

(2) Pigment 2 (Coated with a Inorganic Alkoxide)

The forming method of pigment 2 is the same as that of pigment 1, wherein the pigment was replaced with carbo black MA7 (from Mistsubishi).

(3) Pigment 3 (Coated with a Inorganic Alkoxide)

The forming method of pigment 3 is the same as that of pigment 1, wherein the pigment was replaced with Pigment Green 36(from BASF).

(4) Pigment 4 (Coated with a Inorganic Alkoxide)

The forming method of pigment 4 is the same as that of pigment 1, wherein the pigment was replaced with Pigment Blue 15:6 (from BASF).

### 4. Preparation of the Heat-Resistant Flexible Color Filter

### (1) Example 1

Under nitrogen atmosphere, 10 g of Pigment 1 mentioned above, 80 g PGMEA and 5.5 g dispersant (from SOLSPERSE, catalog number 22000, 0.5 g, and catalog number 24000, 5 g) are added in to a 250 ml polyethylene (PE) grinding tank containing ½ the grinding tank volume of zirconium balls with a diameter of 1 mm to form a mixed solution and the mixed solution was dispersed by the grinding machine for 4 hours, and the zirconium balls were filtered out to obtain a dispersion solution. 96.7 g PGMEA, 20 g acrylic resin solution, 6 g reactive dipentaerythritol hexaacrylate monomer, 0.5 g isopropylthioxanthone (ITX) initiator and 4.5 g (2-Benzyl-2-(dimethylamino)-1-[4-(4-morpholinyl)phenyl]-1-butanone (I369) were mixed and stirred to be dissolved to form a photosensitive resin.

During the stirring process, the dispersion solution was added to the photosensitive resin and stirred for 2 hours to complete the preparation of the photosensitive color photoresist. The prepared photosensitive color photoresist material was coated on the substrate 1 mentioned above by spin coating with the rotational speed of 600 rpm and 900 rpm for 15 and 20 seconds, respectively, then pre-baked for 2 minutes, exposed with a mask by UV light with an energy of 150 mj/cm² and then developed with 0.5% KOH alkaline solution, wherein the unexposed part was washed out by the alkaline solution. After washing with water and drying, the maintained pattern was baked at 230° C. for 1 hour to complete the heat-resistant flexible color filter.

### (2) Example 2

The forming method of Example 2 is the same as that of Example 1, wherein the pigment was replaced with coated black pigment, Pigment 2 mentioned above.

### (3) Example 3

The forming method of Example 3 is the same as that of Example 1, wherein the pigment was replaced with coated green pigment, Pigment 3 mentioned above.

### (3) Example 3

The forming method of Example 3 is the same as that of Example 1, wherein the pigment was replaced with coated green pigment, Pigment 3 mentioned above.

### (4) Example 4

The forming method of Example 4 is the same as that of Example 1, wherein the pigment was replaced with coated blue pigment, Pigment 4 mentioned above.

### Comparative Example 1

The forming method of Comparative example 1 is the same as that of Example 1, wherein the pigment was replaced with uncoated Pigment Red 254 (from Ciba).

### Comparative Example 2

The forming method of Comparative example 2 is the same as that of Example 1, wherein the pigment was replaced with uncoated Pigment MA7 (from Mitsubish).

### Comparative Example 3

The forming method of Comparative example 3 is the same as that of Example 1, wherein the pigment was replaced with uncoated Pigment Green 36 (from BASF).

### Comparative Example 4

The forming method of Comparative example 4 is the same as that of Example 1, wherein the pigment was replaced with uncoated Pigment Blue 15:6 (from BASF).

The properties of Examples and Comparative examples are shown in Table 3.

TABLE 3
Properties of Examples and Comparative examples

| | | | | Weight analysis | Coefficient of | |
|---|---|---|---|---|---|---|
| | | 3- | | (temperature of | thermal expansion | |
| | Pigment | Aminopropyl | Triethoxymethyl | 5% weight loss | (out of plane ppm/ | |
| | (g) | triethoxysilane | silane | (° C.) | ° C.)(100-250° C.) | ΔEab |
| Example 1 | PR254 | 5 | 5 | 257 | 14.33 | 0.48 |
| | (40 g) | | | | | |
| Example 2 | Black | 5 | 5 | 267 | 13.39 | 0.78 |
| | (40 g) | | | | | |
| Example 3 | Green | 5 | 5 | 223 | 28.55 | 1.43 |
| | (40 g) | | | | | |
| Example 4 | Blue | 5 | 5 | 261 | 9.1 | 2.60 |
| | (40 g) | | | | | |
| Comparative | PR254 | NA | NA | 202 | 19.85 | 3.33 |
| example 1 | | | | | | |
| Comparative | Black | NA | NA | 220 | 18.75 | — |
| example 2 | | | | | | |
| Comparative | Green | NA | NA | 211 | 47.34 | 2.28 |
| example 3 | | | | | | |
| Comparative | Blue | NA | NA | 218 | 14.11 | 3.20 |
| example 4 | | | | | | |

In order to estimate the quality of development for the pigments of the examples and comparative examples on the nano silica/polyimide hybrid substrate (ie. after developing the scum on the substrate), the transparency of the pix, for which the photoresist material with the pigments was completely developed and removed, was defined as 100%. After being developed, the transparency of the pix on which scum attached was less than 100%. Therefore, the transparency of the pix after developing was used to define the scum level. The higher the transparency was, the less scum there was.

Table 3, shows that between the nano silica/polyimide hybrid substrate and the heat stable pigment coated photoresist material, there exist advantages of good interface compatibility, good quality of development, low coefficient of thermal expansion and low chromatism, etc.

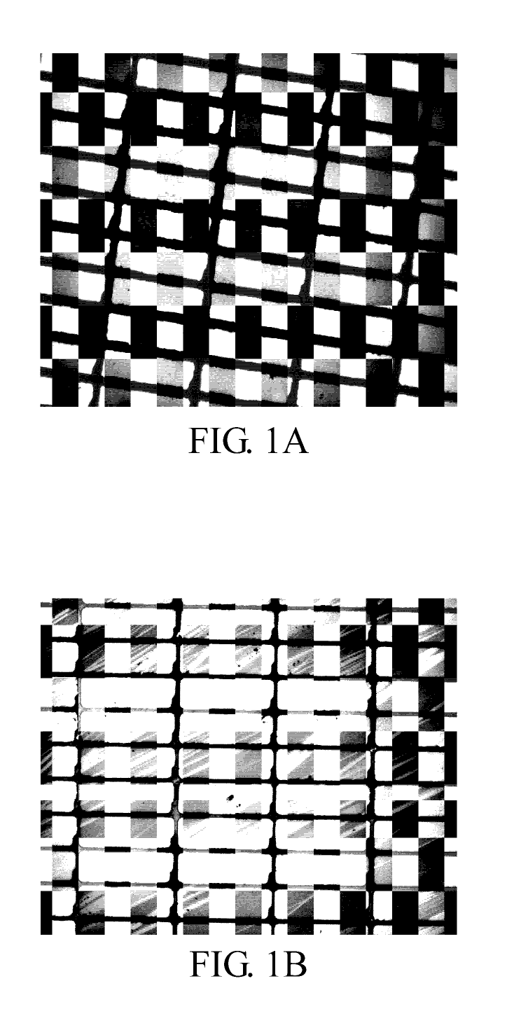

Furthermore, FIG. 1A and FIG. 1B display the optical microscope photographs of Example 2 and Comparative example 2 respectively, after development. According to FIG. 1A and FIG. 1B, it is shown that the bottom layer of Example 2 has no scum while the bottom layer of Comparative example 2 has significant levels of scum.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat-resistant flexible color filter, comprising:
a flexible transparent substrate, wherein the forming material thereof comprises nano silica and polyimide, and the nano silica is present in an amount of about 20-70 wt %, based on 100 wt % of the forming material; and
a heat-stable color photoresist material coated on the flexible transparent substrate, wherein the heat stable color photoresist material comprises:
a base soluble resin system about 30-90 wt %;
a photosensitive system about 5-60 wt %; and
a pigment coated with an inorganic alkoxide about 10-50 wt %.

2. The heat-resistant flexible color filter as claimed in claim 1, wherein the forming material of the flexible transparent substrate further comprises a siloxane surfactant.

3. The heat-resistant flexible color filter as claimed in claim 2, wherein the siloxane surfactant comprises a siloxane surfactant with polar functional groups.

4. The heat-resistant flexible color filter as claimed in claim 3, wherein the siloxane surfactant with polar functional groups is aminosiloxane.

5. The heat-resistant flexible color filter as claimed in claim 1, wherein a formula of the polyimide is represented by formula (I): 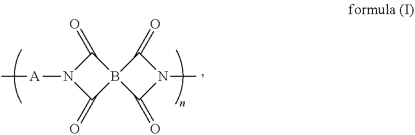
wherein, n is an integer about of 15-10000;
A is cycloalkyl group, heterocyclic group, cycloalkyl group or heterocyclic group with one or more unsaturated bond, aryl group, heteroaryl group, aliphatic group, cycloaliphatic diene group, arylalkyl group or heteroarylalkyl group, and each ring has 3 to 8 carbon atoms; and
B is one or more kinds of cycloalkyl group, heterocyclic group, cycloalkyl group or heterocyclic group with one or more unsaturated bond, aryl group, heteroaryl group, aliphatic group, cycloaliphatic diene group, arylalkyl group or heteroarylalkyl group, and each ring has 3 to 8 carbon atoms.

6. The heat-resistant flexible color filter as claimed in claim 5, wherein a hydrogen atom bonded to a cyclic atom of A is substituted by halogen, alkyl group, thioalkyl group, alkoxy group, alkenyl group, alkynyl group, alkenoxy group alkynoxy group or aryl group, and wherein the alkyl group, thioalkyl group, alkoxy group, alkenyl group, alkynyl group, alkenoxy group or alkynoxy group has 1 to 12 carbon atoms and is straight or branched.

7. The heat-resistant flexible color filter as claimed in claim 5, wherein A is 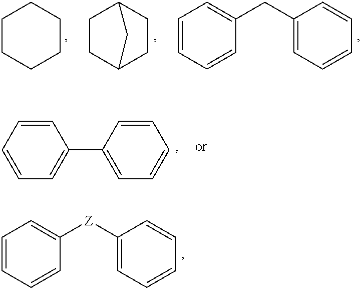
and wherein Z is O, —CH₂—, —C(CH₃)₂—, —Ar—O—Ar—, Ar—CH₂—Ar—, —Ar—C(CH₃)₂—Ar— or —Ar—SO₂—Ar—, and Ar represents benzene.

8. The heat-resistant flexible color filter as claimed in claim 5, wherein A is 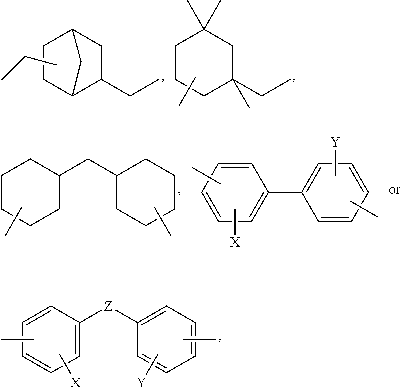
and wherein X and Y are —H, —CH₃, —R, —CF₃, —OH, —OR, —Br, —Cl or —I, and R represents an alkyl group having 1-18 carbon atoms, and Z is —O—, —S—, —CH₂—, —C(CH₃)₂—, —SO₂—, —Ar—O—Ar—, —Ar—CH₂—Ar—, —O—Ar—Ar—O—, —O—Ar—C(CF₃)₂—Ar—O—, —O—Ar—C(CH₃)₂—Ar—O—, —O—Ar—SO₂—Ar—O—, and Ar represents benzene.

9. The heat-resistant flexible color filter as claimed in claim 5, wherein a hydrogen atom bonded to a cyclic atom of B is substituted by halogen, alkyl group, thioalkyl group, alkoxy group, alkenyl group, alkynyl group, alkenoxy group alkynoxy group or aryl group and wherein the alkyl group, thioalkyl group, alkoxy group, alkenyl group, alkynyl group, alkenoxy group or alkynoxy group has 1 to 12 carbon atoms and is straight or branched.

10. The heat-resistant flexible color filter as claimed in claim 5, wherein B is 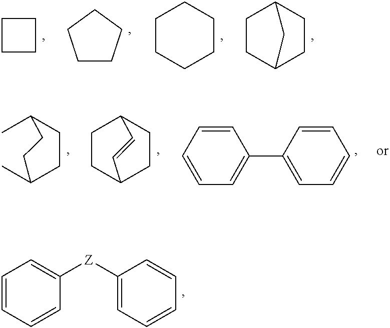
and wherein Z is O, —CH₂—, —C(CH₃)₂—, —Ar—O—Ar—.Ar—CH₂—Ar—, —Ar—C(CH₃)₂—Ar— or —Ar—SO₂—Ar—, and Ar represents benzene.

11. The heat-resistant flexible color filter as claimed in claim 5, wherein B is 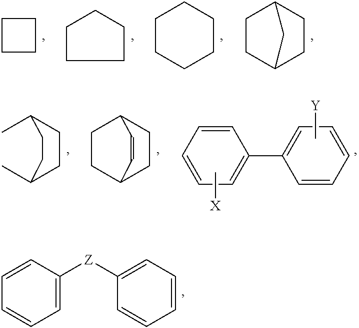
and X and Y are —H, —CH₃, —R, —CF₃, —OH, —OR, —Br, —Cl or —I, and R represents an alkyl group having 1-18 carbon atoms, and Z is —O—.—S—, —CH₂—, —C(CH₃)₂—, —SO₂—, —Ar—O—Ar—, —Ar—CH₂—Ar—, —O—Ar—Ar—O—, —O—Ar—C(CF₃)₂—Ar—O—, —O—Ar—C(CH₃)₂—Ar—O—, —O—Ar—SO₂—Ar—O—, and Ar represents benzene.

12. The heat-resistant flexible color filter as claimed in claim 1, wherein the base soluble resin system comprises a base soluble resin.

13. The heat-resistant flexible color filter as claimed in claim 12, wherein the base soluble resin comprises an acrylic polymer with an acid group.

14. The heat-resistant flexible color filter as claimed in claim 13, wherein the acid group comprises methacrylic acid or acrylic acid.

15. The heat-resistant flexible color filter as claimed in claim 12, wherein the base soluble resin comprises a homopolymer or copolymer of vinylated unsaturated monomers.

16. The heat-resistant flexible color filter as claimed in claim 12, wherein the base soluble resin comprises a copolymer of vinylated unsaturated monomers with silane structures and vinylated unsaturated monomers without silane structures.

17. The heat-resistant flexible color filter as claimed in claim 16, wherein the vinylated unsaturated monomers with silane structures are present in an amount less than about 20 mol %, based on 100 mol % of the copolymer.

18. The heat-resistant flexible color filter as claimed in claim 12, wherein the base soluble resin comprises a copolymer of vinylated unsaturated monomers with acid groups and vinylated unsaturated monomers with silane structures.

19. The heat-resistant flexible color filter as claimed in claim 18, wherein a mole ratio of the vinylated unsaturated monomers with acid groups in the copolymer is about 10-50%, and a weight average molecular weight (g/mol) of the copolymer is about 1,000-100,000.

20. The heat-resistant flexible color filter as claimed in claim 1, wherein the photosensitive system comprises more than two multifunctional monomers with double bonds, and a photoinitiator.

21. The heat-resistant flexible color filter as claimed in claim 21, wherein the photoinitiator is applicable to a wavelength less than 400 nm.

22. The heat-resistant flexible color filter as claimed in claim 1, wherein the inorganic alkoxide comprises metal alkoxide or silicon metal alkoxide.

23. The heat-resistant flexible color filter as claimed in claim 22, wherein the metal alkoxide comprises titanium alkoxide.

24. The heat-resistant flexible color filter as claimed in claim 1, wherein a structure of the inorganic alkoxide is represented by formula (II):
R-M-(OR′)ₙX₃₋ₙ formula (II),
wherein, R is H, C₁₋₁₈ alkyl group, aryl group, alkyl vinyl group, alkyl amine group, alkyl nitrile, alkyl isocyanate, alkyl epoxide group or OR′,
R′ is C₁₋₆ alkyl group, X is halogen, —OH, —NCO or C₁₋₆ alkyl group, and n is an integer about of 1-3.
